(19) United States
(12) Patent Application Publication
(10) Pub. No.: US 2026/0314157 A1
(43) Pub. Date: Oct. 8, 2026

(54) SOLAR CELL MODULE

(71) Applicant: TOYOTA JIDOSHA KABUSHIKI KAISHA, Toyota-shi (JP)

(72) Inventor: Atsushi HOMBE, Toyota-shi (JP)

(73) Assignee: TOYOTA JIDOSHA KABUSHIKI KAISHA, Toyota-shi (JP)

(21) Appl. No.: 19/463,442

(22) Filed: Jan. 29, 2026

(30) Foreign Application Priority Data
Apr. 4, 2025 (JP) 2025-062430

(51) Int. Cl. H10K 30/88; H10K 30/40; H10K 39/10

(52) U.S. Cl. CPC H10K 30/88; H10K 30/40; H10K 39/10

(57) ABSTRACT

The solar cell module includes a substrate having light-transmitting properties, a first electrode, a first carrier transport layer, a photoelectric conversion layer, a second carrier transport layer, a buffer layer, and a second electrode in this order. The substrate has a recess including a bottom wall portion extending along a plane of the photoelectric conversion layer and covering the first electrode, and a side wall portion extending in a thickness direction of the photoelectric conversion layer. The side wall portion is provided so as to cover at least a side surface of the first electrode, a side surface of the first carrier transport layer, and a side surface of the photoelectric conversion layer.

### CROSS-REFERENCE TO RELATED APPLICATION

This application claims priority to Japanese Patent Application No. 2025-062430 filed on Apr. 4, 2025. The disclosure of the above-identified application, including the specification, drawings, and claims, is incorporated by reference herein in its entirety.

### BACKGROUND

### 1. Technical Field

The present disclosure relates to solar cell modules.

### 2. Description of Related Art

For example, such a technology is described in Japanese Unexamined Patent Application Publication No. 2022-34875 (JP 2022-34875 A). The solar cell module described in JP 2022-34875 A includes a substrate, a first electrode provided on the substrate, a photoelectric conversion layer provided on the first electrode, a second electrode provided on the photoelectric conversion layer, and a barrier layer. The barrier layer is provided so as to cover a side surface of the photoelectric conversion layer. In this solar cell module, the barrier layer is a dense inorganic material layer and serves as a moisture-proof layer that suppresses moisture ingress through the side surface of the photoelectric conversion layer, thereby reducing the likelihood of moisture-induced deterioration of the solar cell.

### SUMMARY

In the above solar cell module, however, the barrier layer serving as the moisture-proof layer is discontinuous at its end, which allows moisture to enter through that discontinuous region.

The present disclosure has been made in view of such an issue, and an object thereof is to provide a solar cell module capable of suppressing moisture ingress through the side surface of the photoelectric conversion layer.

A solar cell module according to the present disclosure includes, a substrate having light-transmitting properties, a first electrode, a photoelectric conversion layer containing a perovskite compound, and a second electrode, in an order of the substrate, the first electrode, the photoelectric conversion layer, and the second electrode. The substrate has a recess including a bottom wall portion and a side wall portion. The bottom wall portion extends along the plane of the photoelectric conversion layer and covers the first electrode. The side wall portion extends in the thickness direction of the photoelectric conversion layer. The side wall portion is provided so as to cover at least a side surface of the first electrode and a side surface of the photoelectric conversion layer.

In the solar cell module according to the present disclosure, the substrate includes the recess that includes: the bottom wall portion extending along the plane of the photoelectric conversion layer and covering the first electrode; and the side wall portion extending in the thickness direction of the photoelectric conversion layer. The side wall portion of the substrate is provided so as to cover at least the side surface of the first electrode and the side surface of the photoelectric conversion layer. By covering the side surface of the photoelectric conversion layer with the side wall portion of the substrate, moisture ingress through the side surface of the photoelectric conversion layer can be suppressed. As a result, the likelihood of deterioration of the photoelectric conversion layer due to moisture ingress is reduced, and a decrease in the power generation efficiency of the solar cell module can be suppressed.

In the solar cell module according to the present disclosure, of an inner surface of the bottom wall portion and an inner surface of the side wall portion, at least the inner surface of the side wall portion may be provided with a moisture-proof layer made of an oxide. With this configuration, moisture ingress is suppressed not only by the side wall portion of the substrate but also by the moisture-proof layer provided on the inner surface of the side wall portion. The cooperation between the side wall portion and the moisture-proof layer further enhances the ability to suppress moisture ingress through the side surface of the photoelectric conversion layer.

In the solar cell module according to the present disclosure, the side wall portion may be inclined such that the space of the recess widens from the bottom wall portion toward an opening of the recess. This configuration makes it easier to form the moisture-proof layer on the inner surface of the side wall portion, thereby improving the film formability of the moisture-proof layer.

The present disclosure can suppress moisture ingress through the side surface of the photoelectric conversion layer.

### BRIEF DESCRIPTION OF THE DRAWINGS

Features, advantages, and technical and industrial significance of exemplary embodiments of the disclosure will be described below with reference to the accompanying drawings, in which like signs denote like elements, and wherein:

FIG. 1 is a schematic cross-sectional view showing a solar cell module according to a first embodiment;

FIG. 2A is a schematic view illustrating manufacturing of a substrate having a recess;

FIG. 2B is a schematic view illustrating manufacturing of a substrate having a recess;

FIG. 3 is a schematic cross-sectional view showing a solar cell module according to a second embodiment;

FIG. 4A is a schematic view illustrating manufacturing of a substrate having a recess and formation of a moisture-proof layer;

FIG. 4B is a schematic view illustrating manufacturing of a substrate having a recess and formation of a moisture-proof layer;

FIG. 4C is a schematic view for explaining the manufacturing of a substrate having a recess and formation of a moisture-proof layer;

FIG. 5 is a schematic cross-sectional view showing a solar cell module according to a third embodiment;

FIG. 6A is a schematic view illustrating manufacturing of a substrate having a recess and formation of a moisture-proof layer.

FIG. 6B is a schematic view illustrating manufacturing of a substrate having a recess and formation of a moisture-proof layer; and

FIG. 6C is a schematic view illustrating manufacturing of a substrate having a recess, and formation of a moisture-proof layer.

### DETAILED DESCRIPTION OF EMBODIMENTS

Hereinafter, an embodiment of a solar cell module according to the present disclosure will be described with reference to the drawings. In the description of the drawings, the same elements are denoted by the same reference numerals, and redundant description thereof will be omitted. Further, in the following description, unless otherwise specified, the "side surface" refers to an end surface along the light incident direction (in other words, an end surface parallel to the light incident direction) on the assumption that light is incident perpendicularly to the solar cell module. "Moisture" includes water, water vapor, and the like. Further, the "thickness" referred to in the following description refers to the distance in the direction of light incidence.

### First Embodiment

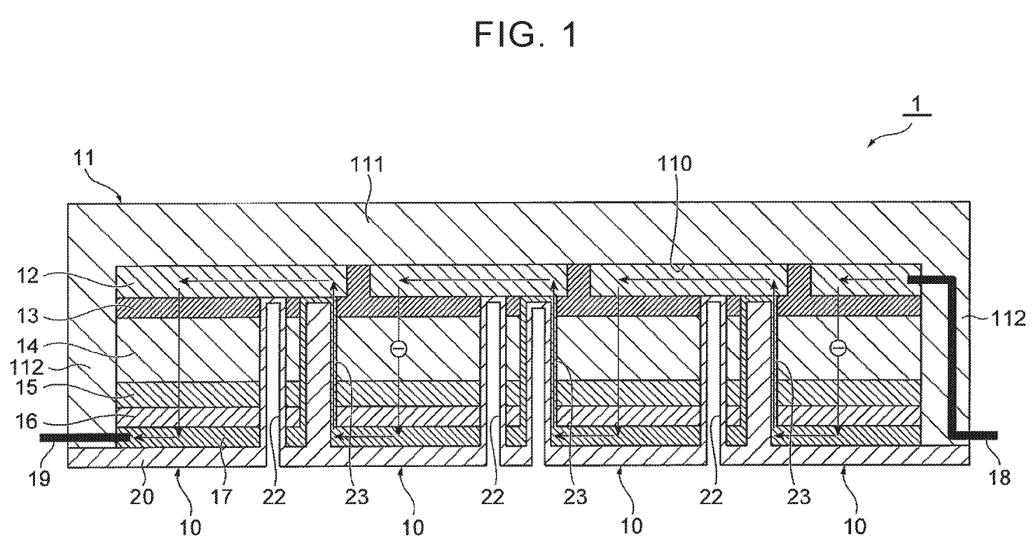

FIG. 1 is a schematic cross-sectional view showing a solar cell module according to a first embodiment. The solar cell module 1 of the present embodiment is, for example, a thin-plate perovskite solar cell, and includes a plurality of cells 10 arranged side by side along one direction (for example, a longitudinal direction) of the solar cell module 1.

As shown in FIG. 1, the solar cell module 1 of the present embodiment includes a substrate 11, a first electrode 12, a first carrier transport layer 13, a photoelectric conversion layer 14, a second carrier transport layer 15, a buffer layer 16, and a second electrode 17. The first electrode 12, the first carrier transport layer 13, the photoelectric conversion layer 14, the second carrier transport layer 15, the buffer layer 16, and the second electrode 17 are stacked on the substrate 11 in this order.

The substrate 11 is an insulating substrate having light-transmitting properties, and is made of, for example, glass or resin. The substrate 11 is patterned to be connected in series. Examples of the resin having light-transmitting properties include polyethylene terephthalate, polyethylene naphthalate, polyimide, polyamide, polyamideimide, and cycloolefin polymer. The substrate 11 may be a flexible sheet or film. As will be described later, the substrate 11 of the present embodiment includes a recess 110 having a bottom wall portion 111 and a side wall portion 112. The thickness of the bottom wall portion 111 is, for example, about 0.1 mm.

The first electrode 12 is a positive electrode that collects holes, and is formed of a transparent conductive oxide (TCO: Transparent Conductive Oxide) having conductivity and light-transmitting properties. Examples of the transparent conductive oxide include indium oxide, tin oxide, zinc oxide, titanium oxide, and composite oxides thereof. Among them, from the viewpoint of higher conductivity and transparency, an indium-based complex oxide containing indium oxide as a main component is preferable, and elements such as Sn, W, and Zn, Ti may be further added as dopants. In the present embodiment, the first electrode 12 is made of a metallic oxide having light-transmitting properties such as ITO (Indium Tin Oxide), and the thickness thereof is, for example, about 150 nm.

The first carrier transport layer 13 is, for example, a hole transport layer, and its thickness is, for example, about 2 nm. As the hole transport layer, a known organic material or inorganic material that can be used for the hole transport layer can be used. Examples of the organic compound include 2,2′,7,7′-tetrakis-(N,N-di-4-methoxyphenylamino)-9,9′-spirobifluorene (Spiro-OMeTAD), polyethylenedioxythiophene:polystyrenesulfonate (PEDOT:PSS), and poly[bis(4-phenyl)(2,4,6-trimethylphenyl)amine] (PTAA). Examples of the inorganic material include nickel oxide and copper oxide.

The photoelectric conversion layer 14 is a flat layer containing a perovskite compound and has a thickness of, for example, about 550 nm. That is, the photoelectric conversion layer 14 is a layer that can convert the irradiated light energy into electric energy, absorbs the light received by the solar cell module 1, and converts the light into free electrons and holes. In the present embodiment, the photoelectric conversion layer 14 is a perovskite layer containing a compound having a perovskite crystal structure as a main material. Examples of the compound include lead methylammonium halide, lead methylammonium iodide, and the like, or a part of the halogen atom may contain a bromine atom or a chlorine atom.

The second carrier transport layer 15 is, for example, an electron transport layer, and the thickness thereof is, for example, about 40 nm. As the electron transport layer, a known organic material or inorganic material that can be used for the electron transport layer can be used. Examples of the organic material include fullerene compounds, phenanthroline derivatives, and polyethyleneimines. Examples of the inorganic material include titanium oxide, tin oxide, and zinc oxide.

The buffer layer 16 is a layer for improving the photoelectric conversion efficiency, and is formed of, for example, an organic semiconductor. The thickness of the buffer layers 16 is, for example, about 30 nm. Note that the buffer layer 16 is not necessarily required and may be omitted.

The second electrode 17 is an electrode that forms a pair with the first electrode 12, and is a negative electrode in the present embodiment. The second electrode 17 may be made of a material similar to that of the first electrode 12, but may not have light transmittance unlike the first electrode 12. In the present embodiment, the second electrode 17 is made of IZO (Indium Zinc Oxide) and has a thickness of, for example, about 200 nm.

In the solar cell module 1 having the structure as described above, the substrate 11, the first electrode 12, and the first carrier transport layer 13 have light-transmitting properties. Therefore, when light such as sunlight is irradiated from the substrate 11 side, the light passes through these portions and reaches the photoelectric conversion layer 14. The light reaching the photoelectric conversion layer 14 is absorbed by the photoelectric conversion layer 14 with irradiation light having a specific wavelength. The absorbed light is converted into a plurality of holes and free electrons. The converted holes and free electrons move to the first carrier transport layer (hole transport layer) 13 and the second carrier transport layer (electron transport layer) 15, respectively, and are then collected by the first electrode 12 and the second electrode 17. As a result, the solar cell module 1 generates electric power.

Further, the solar cell module 1 of the present embodiment includes a moisture-proof layer 20 that suppresses moisture ingress. The moisture-proof layer 20 is formed of a metallic oxide or an inorganic oxide (for example, Al₂O₃, TiO₂, ZnO, SnO₂). In the present embodiment, the moisture-proof layer 20 is a dense inorganic material layer (the density of the inorganic material is high). The moisture-proof layer 20 is formed to cover the second electrode 17 and also cover the side surface of the second electrode 17, the side surface of the buffer layer 16, the side surface of the second carrier transport layer 15, the side surface of the photoelectric conversion layer 14, and the side surface of the first carrier transport layer 13. The thickness of the moisture-proof layer 20 is, for example, 40 nm or less.

When the moisture-proof layer 20 is formed of a dense inorganic material layer, the moisture-proof layer serves as a moisture-proof function and can also suppress a decrease in the moisture-proof effect caused by ultraviolet rays, temperature changes, and the like. The moisture-proof layer 20 is formed by, for example, an atomic layer deposition method, a sputtering film formation method, a vacuum vapor deposition method, or the like.

The moisture-proof layer 20 preferably has gas barrier properties and insulating properties. Further, the moisture-proof layer 20 may or may not have light-transmitting properties.

As shown in FIG. 1, the solar cell module 1 is evenly divided into a plurality of cells 10 by a plurality of dividing grooves 22. The plurality of cells 10 are arranged side by side along the longitudinal direction of the solar cell module 1 and are connected in series. Further, as shown in FIG. 1, hole extraction electrodes 18 and electron extraction electrodes 19 are provided at both ends in the longitudinal direction of the solar cell module 1.

In the solar cell module 1, electrons enter the first electrode 12 from the hole extraction electrode 18, as indicated by arrows in FIG. 1. The electrons pass through the first carrier transport layer 13, the photoelectric conversion layer 14, the second carrier transport layer 15, the buffer layer 16, and the second electrode 17, and then flow to the first electrode 12 of the adjacent cell 10 via the inter-cell conductive portion 23. In this way, it is finally extracted from the electron extraction electrode 19 via the plurality of cells 10.

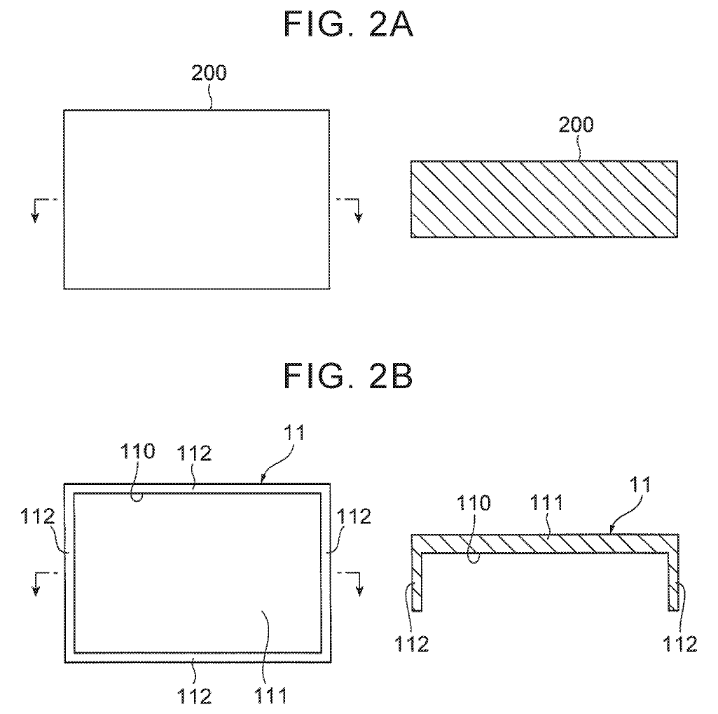

Further, in the present embodiment, the substrate 11 includes a recess 110 having a bottom wall portion 111 that extends along the plane of the photoelectric conversion layer 14 (that is, the longitudinal direction of the solar cell module 1) and covers the first electrode 12, and a side wall portion 112 that extends along the thickness direction of the photoelectric conversion layer 14 (that is, the light incident direction). As shown in FIG. 2B described later, the bottom wall portion 111 has a rectangular shape, and the side wall portion 112 is formed along the four sides of the bottom wall portion 111 so as to surround the bottom wall portion 111.

The side wall portion 112 is formed to cover the side surface of the first electrode 12, the side surface of the first carrier transport layer 13, the side surface of the photoelectric conversion layer 14, the side surface of the second carrier transport layer 15, the side surface of the buffer layer 16, and the side surface of the second electrode 17. The front end surface of the side wall portion 112 in the light incident direction is covered with the moisture-proof layer 20 described above.

The method of manufacturing the solar cell module 1 configured as described above includes, for example, a recess preparation step and a lamination step. In the recess preparation step, as shown in FIG. 2A, first, a plate-shaped substrate 200 is prepared. Next, the plate-shaped substrate 200 is processed to form a recess 110 having a bottom wall portion 111 and a side wall portion 112 (see FIG. 2B). Thereafter, the bottom wall portion 111 and the side wall portion 112 are patterned to be connected in series.

In the lamination step, the first electrode 12, the first carrier transport layer 13, the photoelectric conversion layer 14, the second carrier transport layer 15, the buffer layer 16, and the second electrode 17 are sequentially deposited and laminated on the bottom wall portion 111 of the substrate 11. As the method of forming the electrodes and the layers, those already known in the art can be used, and detailed description thereof will be omitted.

Next, a moisture-proof layer 20 made of an oxide (e.g., Al₂O₃) is formed on the top surfaces of the buffer layer 16 and the side wall portion 112 stacked on the bottom wall portion 111 by, for example, atomic layer deposition (ALD: Atomic Layer Deposition). Thus, the solar cell module 1 is manufactured.

In the solar cell module 1 according to the present embodiment, the substrate 11 includes a recess 110 having a bottom wall portion 111 extending along the longitudinal direction of the solar cell module 1 and covering the first electrode 12, and a side wall portion 112 extending along the light incident direction. The side wall portion 112 is formed to cover the side surface of the first electrode 12, the side surface of the first carrier transport layer 13, the side surface of the photoelectric conversion layer 14, the side surface of the second carrier transport layer 15, the side surface of the buffer layer 16, and the side surface of the second electrode 17. As described above, by covering the side surface of the photoelectric conversion layer 14 with the side wall portion 112 of the substrate 11, moisture ingress through the side surface of the photoelectric conversion layer 14 can be suppressed. As a result, the likelihood of deterioration of the photoelectric conversion layer 14 caused by moisture ingress can be reduced, and a decrease in the power generation efficiency of the solar cell module 1 can be suppressed.

### Second Embodiment

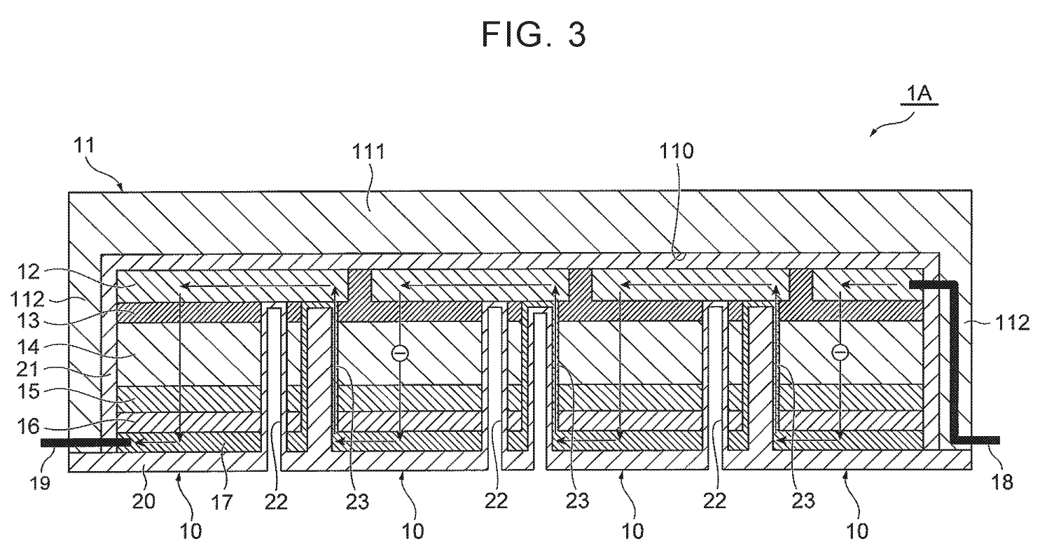

Hereinafter, a second embodiment of a solar cell module will be described with reference to FIG. 3. The solar cell module 1A of the present embodiment is different from the first embodiment in that the moisture-proof layer 21 is formed on the inner surface of the bottom wall portion 111 and on the inner surface the side wall portion 112 of the substrate 11. The other structures are the same as those of the first embodiment, and thus redundant descriptions thereof will be omitted.

FIG. 3 is a schematic cross-sectional view showing a solar cell module according to a second embodiment. As shown in FIG. 3, in the solar cell module 1A of the present embodiment, a moisture-proof layer 21 for suppressing moisture ingress is formed on the inner surface the bottom wall portion 111 and on the inner surface of the side wall portion 112 of the substrate 11. A moisture-proof layer 21 is formed on the inner surface of the bottom wall portion 111 and on the inner surface of the side wall portion 112. Therefore, the moisture-proof layer 21 includes a first portion covering the first electrode 12, a side surface of the first electrode 12, a side surface of the first carrier transport layer 13, a side surface of the photoelectric conversion layer 14, a side surface of the second carrier transport layer 15, a side surface of the buffer layer 16, and a second portion covering the side surface of the second electrode 17.

On the opening side of the recess 110, the front end surface of the moisture-proof layer 21 (more specifically, the front end surface of the second portion of the moisture-proof layer 21) is connected to the moisture-proof layer 20 provided on the second electrode 17 side. In this way, it is possible to reduce moisture ingress due to discontinuities between the moisture-proof layer 20 and the moisture-proof layer 21.

Note that the moisture-proof layer 21 is a dense inorganic material layer and is formed of a metal oxide or an inorganic oxide (for example, Al₂O₃, TiO₂, ZnO, SnO₂) in the same manner as the moisture-proof layer 20 provided on the second electrode 17.

The manufacturing process of the solar cell module 1A configured as described above includes a recess preparation step and a lamination step as in the first embodiment, but since the moisture-proof layer 21 needs to be further formed, the recess preparation step is different from the first embodiment.

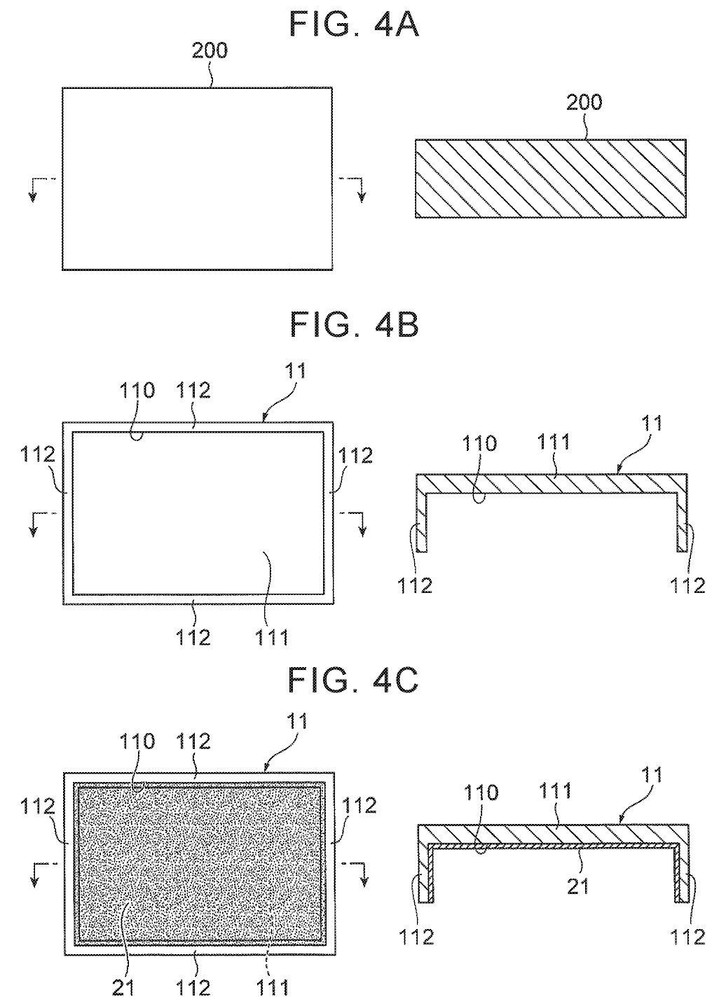

Specifically, in the recess preparation step, as shown in FIG. 4A, first, a plate-shaped substrate 200 is prepared. Next, the plate-shaped substrate 200 is processed to form a recess 110 having a bottom wall portion 111 and a side wall portion 112 (see FIG. 4B). Thereafter, a moisture-proof layer 21 made of an oxide (e.g., Al₂O₃) is formed on the inner wall surface of the bottom wall portion 111 and the inner wall surface of the side wall portion 112 by an atomic layer deposition method (see FIG. 4C).

In the lamination step, the first electrode 12, the first carrier transport layer 13, the photoelectric conversion layer 14, the second carrier transport layer 15, the buffer layer 16, and the second electrode 17 are sequentially deposited and laminated on the moisture-proof layer 21 formed in the bottom wall portion 111. Thereafter, a moisture-proof layer 20 made of an oxide (e.g., Al₂O₃) is deposited on the second electrode 17, the front end surface of the side wall portion 112, and the front end surface of the moisture-proof layer 21 by an atomic layer deposition method.

According to the solar cell module 1A of the present embodiment, the same advantages as those of the first embodiment described above can be obtained. Further, since the moisture-proof layer 21 is further formed on the inner surface of the bottom wall portion 111 and the inner surface of the side wall portion 112, the moisture-proof layer 21 also serves to suppress moisture ingress. That is, in the present embodiment, moisture ingress can be suppressed not only by the side wall portion 112 of the substrate 11 but also by the moisture-proof layer 21 formed on the inner surface of the side wall portion 112 and the inner surface of the bottom wall portion 111. Such cooperation between the side wall portion 112 and the moisture-proof layer 21 further enhances the ability to suppress moisture ingress through the side surface of the photoelectric conversion layer 14.

In the present embodiment, an example of the moisture-proof layer 21 having a first portion covering the first electrode 12, a side surface of the first electrode 12, a side surface of the first carrier transport layer 13, a side surface of the photoelectric conversion layer 14, a side surface of the second carrier transport layer 15, a side surface of the buffer layer 16, and a second portion covering the side surface of the second electrode 17 has been described. However, it is not limited thereto. The moisture-proof layer 21 may have only a portion covering the side surface of the first electrode 12, the side surface of the first carrier transport layer 13, the side surface of the photoelectric conversion layer 14, the side surface of the second carrier transport layer 15, the side surface of the buffer layer 16, and the side surface of the second electrode 17.

### Third Embodiment

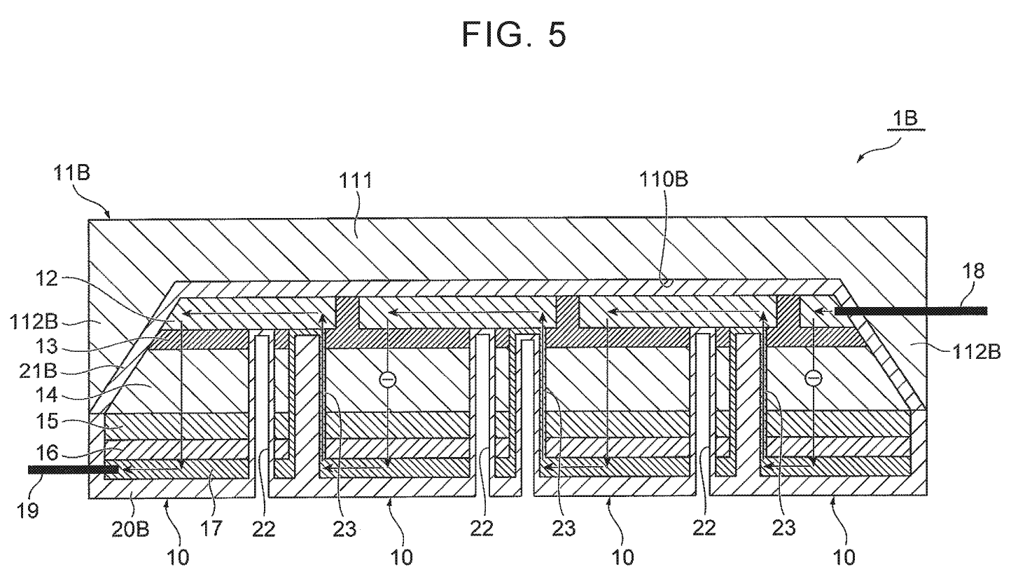

Hereinafter, a third embodiment of a solar cell module will be described with reference to FIG. 5. The solar cell module 1B of the present embodiment is different from the second embodiment described above in the configuration of the side wall portion 112B of the substrate 11B. Since the other structures are the same as those of the second embodiment, redundant description will be omitted.

FIG. 5 is a schematic cross-sectional view showing a solar cell module according to a third embodiment. As shown in FIG. 5, in the solar cell module 1B of the present embodiment, the side wall portion 112B of the substrate 11B is inclined such that the space of the recess 110B widens from the bottom wall portion 111 toward the opening of the recess 110B. More specifically, the side wall portion 112B has a triangular cross section so as to widen from the bottom wall portion 111 toward the opening of the recess 110B, and is formed so as to cover the side surface of the first electrode 12, the side surface of the first carrier transport layer 13, and the side surface of the photoelectric conversion layer 14. On the other hand, the side surface of the second carrier transport layer 15, the side surface of the buffer layer 16, and the side surface of the second electrode 17 are not covered with the side wall portion 112B.

Then, the moisture-proof layer 21B formed on the inner surface of the side wall portion 112B is inclined such that the space of the recess 110B widens so as to conform to the shape of the inner wall surface of the side wall portion 112B. As shown in FIG. 5, the moisture-proof layer 21B is formed to cover the side surface of the first electrode 12, the side surface of the first carrier transport layer 13, and the side surface of the photoelectric conversion layer 14.

Further, in the present embodiment, the moisture-proof layer 20B disposed on the second electrode 17 side is formed to further include a second portion covering the side surface of the second electrode 17, the side surface of the buffer layer 16, and the side surface of the second carrier transport layer 15, in addition to the first portion covering the second electrode 17. In the side surface of the solar cell module 1B, the second portion of the moisture-proof layer 20B is connected to the second portion of the moisture-proof layer 21B. This configuration suppresses moisture ingress due to discontinuities between the moisture-proof layer 20B and the moisture-proof layer 21B.

The manufacturing process of the solar cell module 1B configured as described above includes a recess preparation step and a lamination step as in the second embodiment, but the lamination step is different from the second embodiment due to the difference in the shape of the side wall portion 112B.

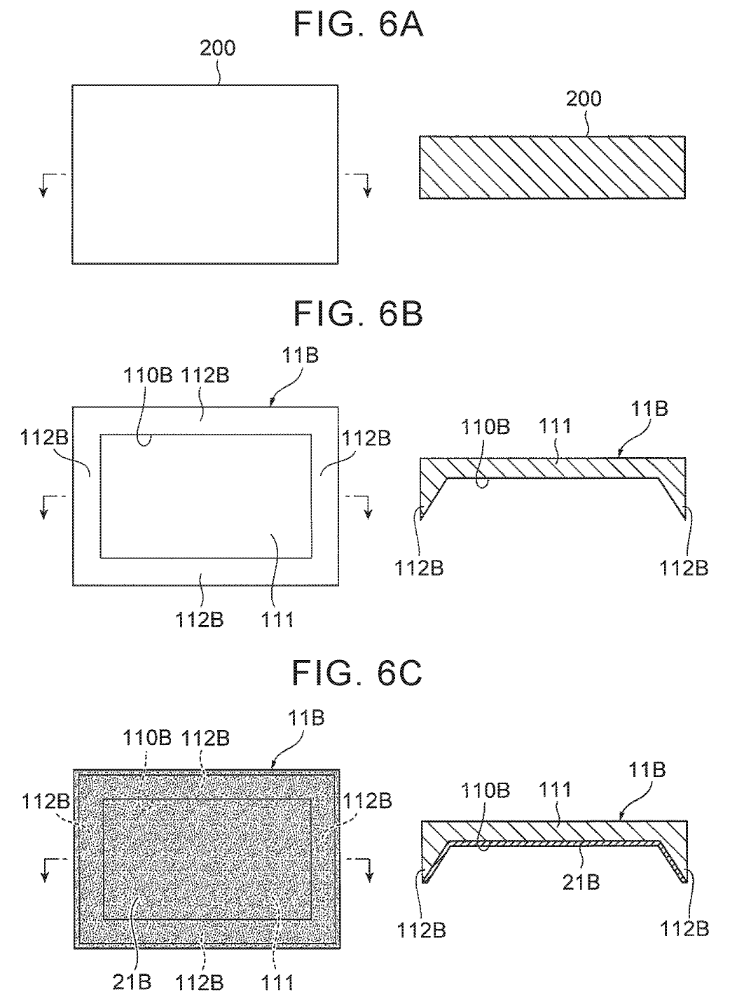

Specifically, in the recess preparation step, as shown in FIG. 6A, first, a plate-shaped substrate 200 is prepared. Next, the plate-shaped substrate 200 is processed to form a recess 110B having the bottom wall portion 111 and the side wall portion 112B (see FIG. 6B). At this time, the side wall portion 112B widens from the bottom wall portion 111 side toward the opening side of the recess 110B, that is, the recess 110B is formed so as to have a triangular cross section.

Thereafter, a moisture-proof layer 21B made of an oxide (e.g., Al₂O₃) is formed on the inner wall surface of the bottom wall portion 111 and the inner wall surface of the side wall portion 112B by an atomic layer deposition method (see FIG. 6C).

In the lamination step, the first electrode 12, the first carrier transport layer 13, the photoelectric conversion layer 14, the second carrier transport layer 15, the buffer layer 16, and the second electrode 17 are sequentially formed and laminated on the moisture-proof layer 21B. The moisture-proof layer 21B is formed on the bottom wall portion 111 and the side wall portion 112B. Thereafter, on the second electrode 17, the front end surface of the moisture-proof layer 21B, the side surface of the second electrode 17, the side surface of the buffer layer 16, and the side surface of the second carrier transport layer 15, a moisture-proof layer 20B made of an oxide (e.g., Al₂O₃) is formed by an atomic layer deposition method.

According to the solar cell module 1B of the present embodiment, the same advantageous effects as those of the second embodiment described above can be obtained. Further, the side wall portion 112B of the substrate 11B is inclined such that the space of the recess 110B widens from the bottom wall portion 111 toward the opening of the recess 110B. Therefore, the moisture-proof layer 21B can be easily formed on the inner surface of the side wall portion 112B, and the film formability of the moisture-proof layer 21B can be improved. Further, the side wall portion 112B is inclined such that the space of the recess 110B widens from the bottom wall portion 111 toward the opening of the recess 110B. Therefore, that the unwanted photoelectric conversion layer 14 can easily escape when the photoelectric conversion layer 14 is formed using, for example, a coating process.

Although the embodiments of the present disclosure have been described in detail above, the present disclosure is not limited to the above-described embodiments, and various design changes can be made without departing from the spirit of the present disclosure described in the claims.

What is claimed is:

1. A solar cell module comprising, a substrate having light-transmitting properties, a first electrode, a photoelectric conversion layer containing a perovskite compound, and a second electrode, in an order of the substrate, the first electrode, the photoelectric conversion layer, and the second electrode, wherein:
the substrate has a recess including a bottom wall portion and a side wall portion, the bottom wall portion extending along a plane of the photoelectric conversion layer and covering the first electrode, and the side wall portion extending in a thickness direction of the photoelectric conversion layer; and
the side wall portion is provided so as to cover at least a side surface of the first electrode and a side surface of the photoelectric conversion layer.

2. The solar cell module according to claim 1, wherein, of an inner surface of the bottom wall portion and an inner surface of the side wall portion, at least the inner surface of the side wall portion is provided with a moisture-proof layer made of an oxide.

3. The solar cell module according to claim 2, wherein the side wall portion is inclined such that a space of the recess widens from the bottom wall portion toward an opening of the recess.
